(19) United States
(12) Patent Application Publication
(10) Pub. No.: US 2023/0187801 A1
(43) Pub. Date: Jun. 15, 2023

(54) Balanced Inductor H-Tree for Powering Energy-Efficient SFQ Circuits

(71) Applicant: International Business Machines Corporation, Armonk, NY (US)

(72) Inventors: Matthew Beck, Danbury, NY (US); John Bulzachelli, Somers, NY (US)

(21) Appl. No.: 17/644,453

(22) Filed: Dec. 15, 2021

(51) Int. Cl. H01P 3/00

(52) U.S. Cl. CPC H01P 3/00

(57) ABSTRACT

An embodiment of the invention may include a circuit structure. The circuit structure may include a wiring tree located between a feeding Josephson transmission line (FJTL) and a global bias line. The circuit may include the wiring tree having an H-tree structure, wherein each branch of the H-tree is connected by a current limiting junction of the FJTL, and wherein a single output port of the H-tree structure is connected to the global bias line. Another embodiment of the invention may include a circuit structure a circuit structure a plurality of feeding Josephson transmission lines (FJTLs) located between a feed line and a global bias line. The path of from the feed line through each FJTL and to the global bias line is substantially similar.

### STATEMENT REGARDING FEDERALLY FUNDED RESEARCH AND DEVELOPMENT

This invention was made with U.S. Government support. The U.S. Government has certain rights in this invention.

### BACKGROUND

The present invention relates generally to a field of heat management on microelectronic devices, and more particularly to a thermal conduction layer to remove the heat generated from a device.

Rapid Single Flux Quantum (RSFQ) technology (and its variants) is a classical computing logic family where logical 0s and 1s are encoded as the absence or presence of a ballistic fluxon (SFQ pulse). Energy Efficient RSFQ (eRSFQ) replaces each resistor used for static biasing of an RSFQ logic circuit with a series-connected bias inductor and a current-limiting Josephson junction (JJ) for dramatically lower static power dissipation.

### BRIEF SUMMARY

Additional aspects and/or advantages will be set forth in part in the description which follows and, in part, will be apparent from the description, or may be learned by practice of the invention.

An embodiment of the invention may include a circuit structure. The circuit structure may include a wiring tree located between a feeding Josephson transmission line (FJTL) and a global bias line. The circuit may include the wiring tree having an H-tree structure, wherein each branch of the H-tree is connected by a current limiting junction of the FJTL, and wherein a single output port of the H-tree structure is connected to the global bias line.

An embodiment of the invention may include a circuit structure a circuit structure a plurality of feeding Josephson transmission lines (FJTLs) located between a feed line and a global bias line. The path of from the feed line through each FJTL and to the global bias line is substantially similar.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1A depicts a prior art arrangement of a eRSFQ powering a bias line, in accordance with the embodiment of the invention.

FIG. 1B depicts a prior art operation of an eRSFQ in powering bias lines, in accordance with the embodiment of the invention.

FIG. 2 depicts an electrical circuit for a symmetric eRSFQ power delivery system, in accordance with the embodiment of the invention.

FIG. 3 depicts an example embodiment of a symmetric eRSFQ, in accordance the embodiment of the present invention.

### DETAILED DESCRIPTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and words used in the following description and claims are not limited to the bibliographical meanings, but, are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces unless the context clearly dictates otherwise.

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the presented embodiments.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. The terms “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” can be understood to include any integer number greater than or equal to one, i.e. one, two, three, four, etc. The terms “a plurality” can be understood to include any integer number greater than or equal to two, i.e. two, three, four, five, etc. The term “connection” can include both an indirect “connection” and a direct “connection.”

As used herein, the term “about” modifying the quantity of an ingredient, component, or reactant of the invention employed refers to variation in the numerical quantity that can occur, for example, through typical measuring and liquid handling procedures used for making concentrates or solutions. Furthermore, variation can occur from inadvertent error in measuring procedures, differences in the manufacture, source, or purity of the ingredients employed to make the compositions or carry out the methods, and the like. The terms “about” or “substantially” are intended to include the degree of error associated with measurement of the particular quantity based upon the equipment available at the time of filing application. For example, “about” can include a range of ±8% or 5%, or 2% of a given value. In one aspect, the term “about” means within 10% of the reported numerical value. In another aspect, the term “about” means within 5% of the reported numerical value. Yet, in another aspect, the term “about” means within 10, 9, 8, 7, 6, 5, 4, 3, 2, or 1% of the reported numerical value. The terms “about” or “substantially” are intended to include the degree of error associated with measurement of the particular quantity based upon the equipment available at the time of filing application.

Various processes used to form a micro-chip that will be packaged into an integrated circuit (IC) fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device.

Reference will now be made in detail to the embodiments of the present invention, examples of which are illustrated in the accompanying drawings, wherein like reference numerals refer to like elements throughout. Rapid Single Flux Quantum (RSFQ) technology (and its variants) is a classical computing logic family where logical 0's and 1's are encoded as the absence or presence of a ballistic fluxon (SFQ pulse). Energy Efficient RSFQ (eRSFQ) replaces each resistor used for static biasing of an RSFQ logic circuit with a series-connected bias inductor and a current-limiting Josephson junction (JJ) for dramatically lower static power dissipation. A feeding Josephson transmission line (FJTL) can be used to generate a stabilized Josephson voltage for the eRSFQ global bias line. When an RF current is applied to the FJTL, a DC voltage develops across the FJTL proportional to the frequency of the RF source. The current-limiting JJs of DUTs regulate currents delivered to their respective circuit cells (by switching and generating a Josephson voltage that balances FJTL rail voltage)

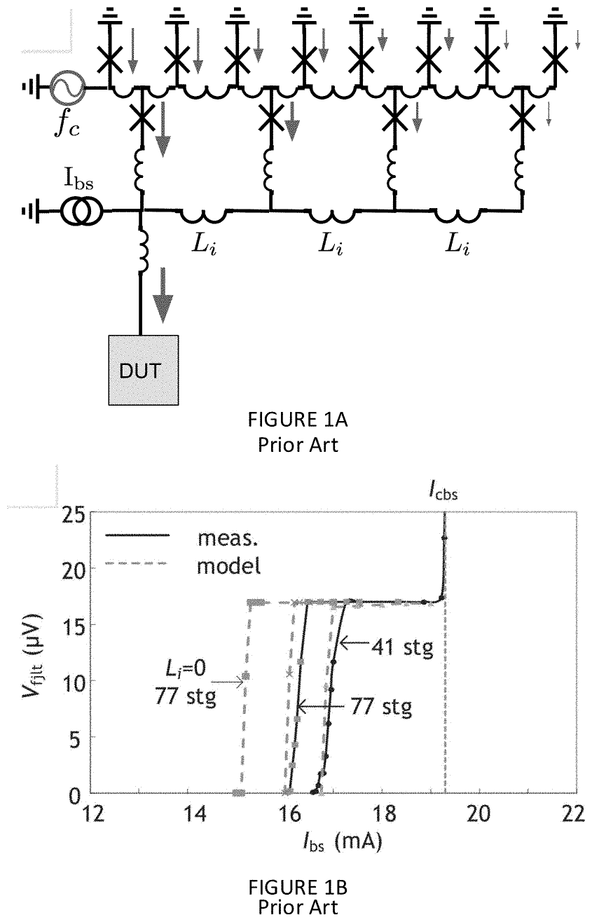

Parasitic inductances along global bias line can cause imbalances in how the DUT load current is drawn from individual FJTL stages. Due to non-uniform loading, some of FJTL stages are forced to source more current than others, and a few FJTL stages may limit the maximum current that the entire FJTL can now supply. Additionally, parasitic inductances between DUTs and different FJTL stages forced uneven current draw, with more current loading of physically closer FJTL JJs (see FIG. 1).

Referring to FIG. 1A a circuit diagram of a previous eRSFQ fJTL power delivery is depicted. If the load circuit (DUT) draws extra current from the global bias line (as indicated by the large arrow), bias currents will be drawn away from the stages of the fJTL (as signified by the other arrows). When the fJTL is connected to the global bias line in a distributed fashion, parasitic series inductances Lᵢ cause an imbalance in how the load current is drawn from the fJTL illustrated by the size/width of the arrows.

Referring to FIG. 1B, measured and modeled performance of the fJTL employed in M. Ketchen, J. Timmerwilke, G. Gibson, and M. Bhushan, “ERSFQ Power Delivery: A Self-Consistent Model/Hardware Case Study,” IEEE Trans. Appl. Supercond., vol. 28, no. 7, October 2019 is depicted. The limiting factor in the range of bias current I_{bs} over which the fJTL generates the correct Josephson voltage is the parasitic inductance Lᵢ. With the parasitic inductance Lᵢ accounted for, the simulated width of the bias voltage “plateau” is close to the measured result but substantially reduced compared to the zero inductance (Lᵢ=0) case.

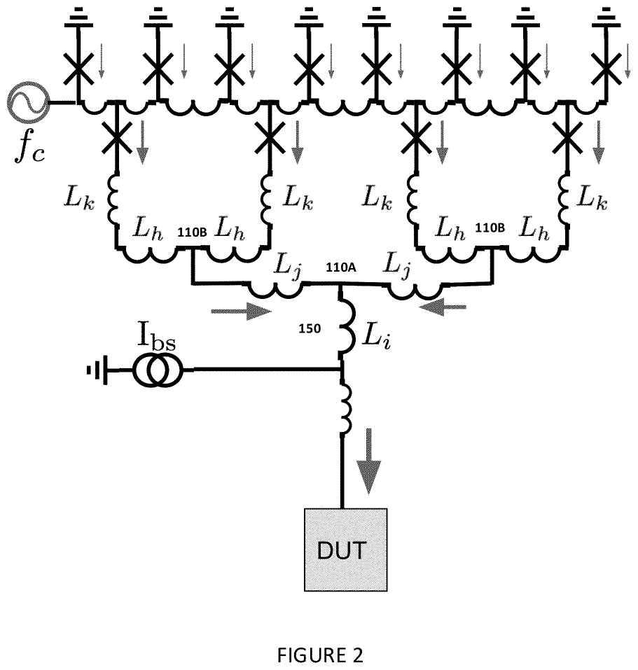

Referring to FIG. 2, a solution to parasitic inductance limitation is depicted. In this architecture, the FJTL is connected to the global bias line via an H-Tree. The inductance to any one of the individual current-limiting junctions of the FJTL is balanced, or substantially balanced, by construction. This in turn enforces an even load current draw (arrows) from every stage of the FJTL. To combat the parasitic inductances that were seen to be limiting the FJTL, by designing a wiring “H-Tree” that naturally balances the inductance to each and every FJTL stage such inductances should be eliminated, or at least minimized. The H-Tree connects to every current-limiting junction in the FJTL chain and is then terminated at a single point on the global bias line. The use of a single termination, together with the balanced inductances (L_{h,i,j,k}) of the H-tree, ensures that the bias current of the load circuitry is drawn evenly from all the stages of the FJTL. This balanced current draw evenly loads each FJTL stage such that the global margins are not limited to that of just a few stages.

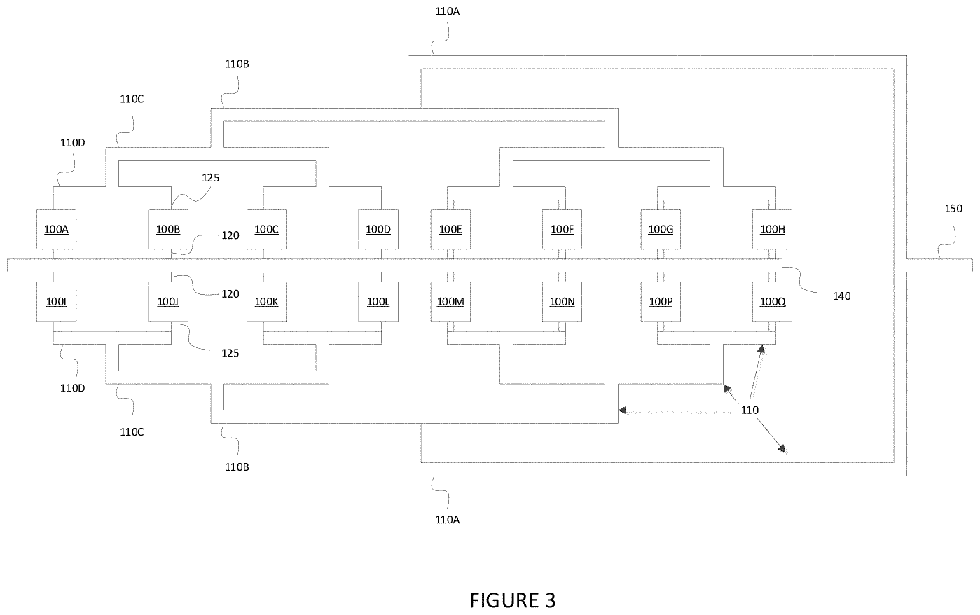

Referring to FIG. 3, a layout of the embodiment of the circuit of FIG. 2 is depicted. A feed line 140 is connected to a plurality of FJTLs (100A-100Q, collectively FJTL 100), each connected to the feed line 140 by a FJTL feed connection 120. Each FJTL 100 is connected to a primary branch 110D of the balanced H-tree 100, with each primary branch 110D having two FJTLs between the primary branch 110D and the feed line. In this embodiment, an first intermediary branch 110C is evenly connected to two primary branches 110D, and a second intermediary branch 110B is evenly connected to two branches of the first intermediary branch 110C. The terminating branch 110A is connected to two branches of the second intermediary branch 110B before leading to the bias line 150. By balancing the construction of the elements such that the paths from each FJTL to the bias line 150 is substantially similar, thus balancing the load across each FJTL via construction.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more embodiment, the practical application or technical improvement over technologies found in the marketplace, or to enable others of ordinary skill in the art to understand the embodiments disclosed herein.

What is claimed is:

1. A circuit structure comprising:
a wiring tree located between a feeding Josephson transmission line (FJTL) and a global bias line;
wherein the wiring tree comprises an H-tree structure, wherein each branch of the H-tree is connected by a current limiting junction of the FJTL, and wherein a single output port of the H-tree structure is connected to the global bias line.

2. A circuit structure comprising:
a plurality of feeding Josephson transmission lines (FJTLs) located between a feed line and a global bias line, wherein a path of from the feed line through each FJTL and to the global bias line is substantially similar.
